(19) United States
(12) Patent Application Publication
(10) Pub. No.: US 2018/0182271 A1
(43) Pub. Date: Jun. 28, 2018

(54) DISPLAY APPARATUSES AND DISPLAY SYSTEMS

(71) Applicants: BOE TECHNOLOGY GROUP CO., LTD., Beijing (CN); Beijing BOE Display Technology Co., Ltd., Beijing (CN)

(72) Inventors: Chunbing Zhang, Beijing (CN); Rui Guo, Beijing (CN); Weihao Hu, Beijing (CN)

(21) Appl. No.: 15/706,346

(22) Filed: Sep. 15, 2017

(30) Foreign Application Priority Data
Dec. 27, 2016 (CN) 201611226554.9

(51) Int. Cl. G09G 3/00; G09G 3/3208; H01L 27/32; H01L 51/52; G09F 9/33

(52) U.S. Cl. CPC G09G 3/001; G09G 3/3208; G09G 2358/00; H01L 51/5234; G09F 9/33; H01L 27/3211

(57) ABSTRACT

The present disclosure provides a display apparatus and a display system. The display apparatus comprises a transparent display layer, a light source layer and a signal controller. The transparent display layer is arranged on a surface of a light exit side of the light source layer; and the signal controller is configured to control operation states of the transparent display layer and the light source layer to realize switching between different modes.

### CROSS-REFERENCE TO RELATED APPLICATION(S)

The present application claims priority to the Chinese Patent Application No. 201611226554.9, filed on Dec. 27, 2016, entitled “DISPLAY APPARATUSES AND DISPLAY SYSTEMS,” which is incorporated herein by reference in its entirety.

### TECHNICAL FIELD

The present disclosure relates to the field of display technology, and more particularly, to a display apparatus and a display system.

### BACKGROUND

At present, display functions of conventional display apparatuses are relatively simple, and display functions cannot be combined to enable a display apparatus to have more complex display functions. In addition, as people's needs for protecting personal information increase, anti-peeping display systems have been paid more and more attention, for the purpose of ensuring security of personal information of users.

In view of people's increasing demands and needs for the display apparatuses, display apparatuses with a variety of display functions and an anti-peeping function are desired, so that the display apparatus may be a multi-use machine.

### SUMMARY

The present disclosure aims to at least partially address one of the technical problems that exist in the conventional technology and to provide a display apparatus and a display system having a variety of display modes and capable of anti-peeping.

According to an aspect of the present disclosure, there is provided a display apparatus. The display apparatus comprises a transparent display layer, a light source layer and a signal controller. The transparent display layer is arranged on a surface of a light exit side of the light source layer; and the signal controller is configured to control operation states of the transparent display layer and the light source layer to realize switching between different modes.

In an embodiment, the modes comprise a picture display mode. The signal controller is configured to: control the transparent display layer to be in a turn-on state and control the light source layer to be in a turn-off state so that the display apparatus is in the picture display mode.

In an embodiment, the signal controller comprises a first control module configured to control the transparent display layer to be in a turn-on state and control the light source layer to be in a turn-off state so that the display apparatus is in the picture display mode.

In an embodiment, the modes comprise an illumination mode. The signal controller is configured to: control the light source layer to be in a turn-on state and control the transparent display layer to be in a turn-off state so that the display apparatus is in the illumination mode.

In an embodiment, the signal controller comprises a second control module configured to control the light source layer to be in a turn-on state and control the transparent display layer to be in a turn-off state so that the display apparatus is in the illumination mode.

In an embodiment, the modes comprise an encryption display mode. The signal controller is configured to: control the transparent display layer to be in a turn-on state and control the light source layer to be in a turn-off state during a first time period of a preset period; and control the light source layer to be in a turn-on state and control the transparent display layer to be in a turn-off state during a second time period of the preset period.

In an embodiment, the signal controller comprises a third control module configured to: control the transparent display layer to be in a turn-on state and control the light source layer to be in a turn-off state during the first time period of the preset period; and control the light source layer to be in a turn-on state and control the transparent display layer to be in a turn-off state during the second time period of the preset period.

In an embodiment, intensity of light emitted from the light source layer is greater than intensity of light emitted from the transparent display layer.

In an embodiment, the transparent display layer is an Organic Light Emitting Diode (OLED) layer.

In an embodiment, the light source layer comprises an area light source, a point light source, or an OLED backlight.

According to another aspect of the present disclosure, there is further provided a display system. The display system comprises the display apparatus according to any of the embodiments described above.

In an embodiment, the display system further comprises shutter glasses. The shutter glasses are paired with the display apparatus and configured to be: in a light transmissive state during the first time period of the preset period; and in a light shading state during the second time period of the preset period.

In an embodiment, the shutter glasses and the display apparatus are paired using a pulse signal.

### BRIEF DESCRIPTION OF THE DRAWINGS

FIG. 1 is a structural diagram of a display apparatus according to an exemplary embodiment of the present disclosure;

FIG. 2 is a structural diagram of a picture display mode according to an exemplary embodiment of the present disclosure;

FIG. 3 is a structural diagram of timing of an illumination mode according to an exemplary embodiment of the present disclosure; and

FIG. 4 is a timing diagram of an encryption display mode according to an exemplary embodiment of the present disclosure.

### DETAILED DESCRIPTION

In order to enable those skilled in the art to have a better understanding of the technical solutions of the present disclosure, the present disclosure will be described in further detail below with reference to the accompanying drawings and specific embodiments.

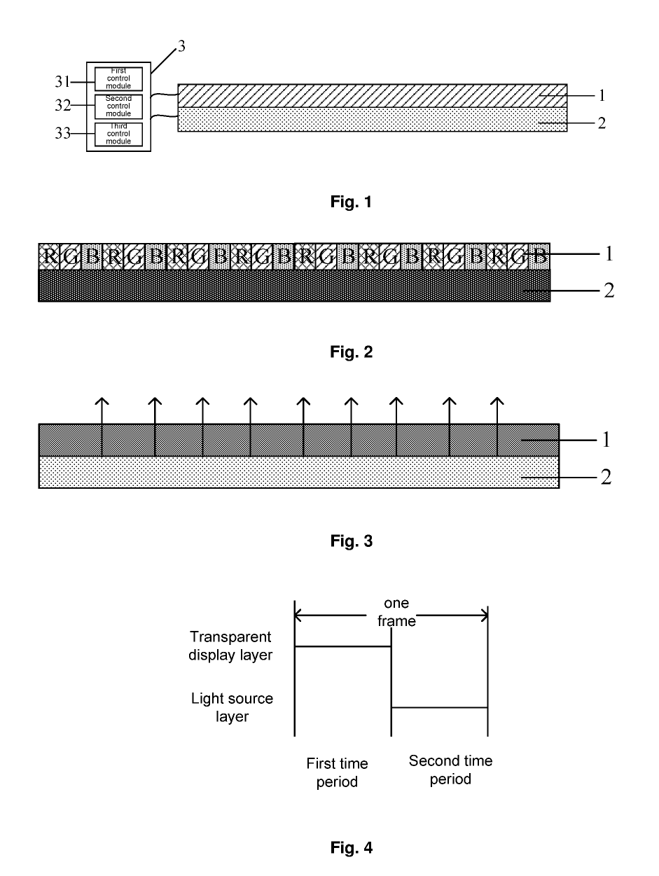

An exemplary embodiment according to the present disclosure is described with reference to FIGS. 1-4.

As shown in FIG. 1, the present embodiment provides a display apparatus. The display apparatus comprises a transparent display layer 1, a light source layer 2 and a signal controller 3. The transparent display layer 1 is arranged on a surface of a light exit side of the light source layer 2. The signal controller 3 is configured to control operation states of the transparent display layer 1 and the light source layer 2 to realize switching between different modes.

It can be understood that the signal controller 3 is electrically connected to the transparent display layer 1 and the light source layer 2 to transmit signals to the transparent display layer 1 and the light source layer 2, so as to control the transparent display layer 1 and the light source layer 2 to be in a turn-on operation state or a turn-off operation state. The transparent display layer 1 is located on the surface of the light exit side of the light source layer 2, so that light emitted from the light source layer 2 may pass through the transparent display layer 1. In the display apparatus according to the present embodiment, switching between different modes can be realized by controlling the operation states of the transparent display layer 1 and the light source layer 2, so that the single display apparatus has a plurality of display functions to realize a multi-use machine.

The modes comprise a picture display mode, and the signal controller 3 controls the transparent display layer 1 to be turned on and control the light source layer 2 to be turned off. Specifically, the signal controller 3 comprises a first control module 31 configured to control the transparent display layer 1 to be in a turn-on state and control the light source layer 2 to be in a turn-off state so that the display apparatus is in the picture display mode.

As shown in FIG. 2, when the display apparatus displays a picture, that is, when the display apparatus is in the picture display mode, the first control module 31 controls the operation state of the transparent display layer 1 to be a turn-on state and controls the operation state of the light source layer 2 to be a turn-off state. At this time, the light source layer 2 does not provide light, and the transparent display layer 1 displays a picture using a display function thereof.

The modes comprise an illumination mode, and the signal controller 3 controls the light source layer 2 to be turned on and controls the transparent display layer 1 to be turned off. Specifically, the signal controller comprises a second control module 32 configured to control the light source layer 2 to be in a turn-on state and control the transparent display layer 1 to be in a turn-off state so that the display apparatus is in the illumination mode.

As shown in FIG. 3, when the display apparatus performs illumination, that is, when the display apparatus is in the illumination mode, the second control module 32 controls the operation state of the transparent display layer 1 to be a turn-off state and controls the operation state of the light source layer 2 to be a turn-on state. That is, light emitted from the light source layer 2 may pass through the transparent display layer 1 for illumination, i.e., realizing illumination. At this time, the transparent display layer 1 does not display any picture and is equivalent to a transparent medium such as glass etc., which may enable the light emitted from the light source layer 2 to directly pass therethrough so as to realize illumination.

The modes comprise an encryption display mode, and the signal controller 3, during a first time period of a preset period, controls the transparent display layer 1 to be in a turn-on state and controls the light source layer 2 to be in a turn-off state, and controls, during a second time period of the preset period, the light source layer 2 to be in a turn-on state and controls the transparent display layer 1 to be in a turn-off state. Specifically, the signal controller 3 comprises a third control module 33 configured to control the transparent display layer 1 to be in a turn-on state and control the light source layer 2 to be in a turn-off state during the first time period of the preset period, and control the light source layer 2 to be in a turn-on state and control the transparent display layer 1 to be in a turn-off state during the second time period of the preset period.

As shown in FIG. 4, the preset period may be display duration of one frame of image, which may comprise a first time period and a second time period. In the first time period, the third control module 33 controls the operation state of the transparent display layer 1 to be a turn-on state and controls the operation state of the light source layer 2 to be a turn-off state, that is, the transparent display layer 1 normally displays a picture and the light source layer 2 does not emit light. In the second time period, the third control module 33 controls the operation state of the transparent display layer 1 to be a turn-off state and controls the operation state of the light source layer 2 to be a turn-on state, that is, the transparent display layer 1 does not display a picture, and the light source layer 2 emits light. As duration of the first time period and the second time period is very short, a user can only see through human eyes that the display apparatus is always in the illumination mode but cannot see any display picture, and the user can see the picture displayed by the display apparatus during the first time period only if he/she wears glasses having the same display frequency as that of the display apparatus, thereby realizing an encryption process, i.e., encrypted display, for the display picture.

It should be understood that although the preset period is described in the present embodiment as comprising the first time period and the second time period, this is only exemplary, and in other embodiments, the preset period may comprise more or less time periods. For example, the preset period may comprise n time periods (where n is an integer greater than 2, for example, an even number greater than 2). In this case, alternation between the picture display mode and the illumination mode may be repeated more times in the display duration of one frame of picture, which can also realize the encryption display mode, and the description thereof will not be repeated here.

It should also be understood that although in the present embodiment, three different display modes are implemented by three different control modules 31, 32 and 33 in the controller 3 respectively, this is only exemplary, and in other embodiments, display in the three different display modes may also be realized using more or less control modules. For example, two control modules, i.e., a control module for the transparent display layer and a control module for the light source layer, may be used to achieve separate control of the transparent display layer and the light source layer, thereby realizing different display modes.

Intensity of light emitted from the light source layer 2, i.e., light emission intensity of the light source layer 2, is greater than light emission intensity of the transparent display layer 1.

The light emission intensity is set in the above manner so that the light emission intensity of the transparent display layer 1 can be submerged in the light emission intensity of the light source layer 2 during encrypted display, to enable a user to only see light through human eyes but cannot see a displayed display picture when observing the display picture in the encryption display mode, thereby realizing encrypted display.

The transparent display layer 1 is an OLED transparent display layer.

The OLED transparent display layer is comprised of multiple RGB sub-pixels, each sub-pixel being comprised of a transparent anode, a semi-transparent cathode and a light-emitting layer. The OLED transparent display layer is used so that the transparent display layer 1 can display a picture without a light source. Of course, if a liquid crystal display layer is used, it is necessary to turn on the light source layer 2 regardless of a display mode, and the display mode of the display apparatus can be controlled only by controlling whether to turn on or turn off the transparent display layer 1.

The light source layer 2 comprises an area light source, a point light source, or an OLED backlight. Of course, the light source layer 2 may also be implemented with other forms of light sources, as long as the light source layer 2 can emit light, and the description thereof is omitted for simplicity.

The display apparatus according to the present embodiment comprises a transparent display layer 1, a light source layer 2 and a signal controller 3. The transparent display layer 1 is located on a surface of the light source layer 2 at a light exit side, and the signal controller 3 may control operation states of the transparent display layer and the light source layer to be a turn-on state or a turn-off state through related timing control, so as to realize switching between different modes. In this way, the display apparatus can integrate multiple display functions such as picture display, illumination display and encrypted display etc., thereby enabling the display apparatus to be a multi-use machine.

The embodiments of the present disclosure further provide a display system comprising the display apparatus according to the embodiments shown in FIGS. 1 to 4. A detailed description of the display apparatus may be known with reference to the above description in conjunction with FIGS. 1 to 4, and will not be repeated here.

The display system further comprises: shutter glasses paired with the display apparatus and configured to be in a light transmissive state during the first time period of the preset period and be in a light shading state during the second time period of the preset period for the display apparatus in the encryption display mode.

It should be noted that the “shutter glasses paired with the display apparatus” as used here means that the shutter glasses and the display apparatus have the same display frequency, that is, in the encryption display mode, when the display apparatus is in the first time period, the shutter glasses is also in the first time period, and when the display apparatus is in the second time period, the shutter glasses are also in the second time period.

When the display apparatus is in the encryption display mode, the display apparatus displays a normal display picture during the first time period. At this time, the shutter glasses are in a light transmissive state, that is, a user may see the display picture through the shutter glasses. The display apparatus can only emit light (i.e., perform illumination) during the second time period. At this time, the shutter glasses is in a light shading state, that is, the shutter glasses shade light emitted from the display apparatus, and the user cannot see the light emitted from the display apparatus. In this case, the user can only see a picture displayed by the display apparatus through the shutter glasses during each time period in which the picture is displayed, without being affected by the time period in which illumination is performed. Therefore, when display pictures are played at a high frequency, a user who does not wear the shutter glasses matched with the display apparatus can only see that the display apparatus is always in the illumination mode, and a user who wears the shutter glasses matched with the display apparatus can see continuous display pictures, thereby realizing the encrypted display.

The shutter glasses and the display apparatus are paired using a pulse signal.

That is, the shutter glasses and the display apparatus are enabled to have the same display frequency by transmitting a pulse signal therebetween, and only if the display frequency of the shutter glasses is the same as that of the display apparatus, the user can see the picture displayed by the display apparatus in the encryption display mode through the shutter glasses. On the contrary, if the shutter glasses and the display device have different display frequencies, even if the user wears the shutter glasses, the user cannot see the picture displayed by the display apparatus in the encryption display mode, and the description thereof will not be repeated here.

In the display system according to the present embodiment, the display apparatus can realize switching between different modes, so that the display apparatus can integrate multiple display functions such as picture display, illumination display, and encrypted display etc., thereby enabling the display apparatus to be a multi-use machine. Further, with the shutter glasses having the same display frequency as that of the display apparatus, a user who wears the shutter glasses can see the display picture in the encryption display mode, and a user who does not wear the shutter glasses having the same display frequency cannot see the picture. In this way, the encrypted display is realized, thereby improving privacy of the display picture.

It is to be understood that the above embodiments are merely exemplary embodiments for the purpose of illustrating the principles of the present disclosure, but the present disclosure is not limited thereto. It will be apparent to those skilled in the art that various changes and modifications can be made therein without departing from the spirit and essence of the present disclosure, which are also considered to be within the protection scope of the present disclosure.

I/We claim:

1. A display apparatus comprising a transparent display layer, a light source layer and a signal controller, wherein:
the transparent display layer is arranged on a surface of a light exit side of the light source layer; and
the signal controller is configured to control operation states of the transparent display layer and the light source layer to realize switching between different modes.

2. The display apparatus according to claim 1, wherein the modes comprise a picture display mode, and the signal controller is configured to:
control the transparent display layer to be in a turn-on state and control the light source layer to be in a turn-off state so that the display apparatus is in the picture display mode.

3. The display apparatus according to claim 2, wherein the signal controller comprises a first control module configured to control the transparent display layer to be in the turn-on state and control the light source layer to be in the turn-off state so that the display apparatus is in the picture display mode.

4. The display apparatus according to claim 1, wherein the modes comprise an illumination mode, and the signal controller is configured to:
control the light source layer to be in a turn-on state and control the transparent display layer to be in a turn-off state so that the display apparatus is in the illumination mode.

5. The display apparatus according to claim 4, wherein the signal controller comprises a second control module configured to control the light source layer to be in the turn-on state and control the transparent display layer to be in the turn-off state so that the display apparatus is in the illumination mode.

6. The display apparatus according to claim 1, wherein the modes comprise an encryption display mode, and the signal controller is configured to:
during a first time period of a preset period, control the transparent display layer to be in a turn-on state and control the light source layer to be in a turn-off state; and
during a second time period of the preset period, control the light source layer to be in a turn-on state and control the transparent display layer to be in a turn-off state.

7. The display apparatus according to claim 6, wherein the signal controller comprises a third control module configured to:
during the first time period of the preset period, control the transparent display layer to be in the turn-on state and control the light source layer to be in the turn-off state; and
during the second time period of the preset period, control the light source layer to be in the turn-on state and control the transparent display layer to be in the turn-off state.

8. The display apparatus according to claim 6, wherein intensity of light emitted from the light source layer is greater than intensity of light emitted from the transparent display layer.

9. The display apparatus according to claim 1, wherein the transparent display layer is an Organic Light Emitting Diode (OLED) layer.

10. The display apparatus according to claim 1, wherein the light source layer comprises an area light source, a point light source, or an OLED backlight.

11. A display system comprising the display apparatus according to claim 1.

12. A display system comprising the display apparatus according to claim 6.

13. A display system comprising the display apparatus according to claim 7.

14. A display system comprising the display apparatus according to claim 8.

15. The display system according to claim 12, further comprising:
shutter glasses paired with the display apparatus and configured to be:
in a light transmissive state during the first time period of the preset period; and
in a light shading state during the second time period of the preset period.

16. The display system according to claim 13, further comprising:
shutter glasses paired with the display apparatus and configured to be:
in a light transmissive state during the first time period of the preset period; and
in a light shading state during the second time period of the preset period.

17. The display system according to claim 14, further comprising:
shutter glasses paired with the display apparatus and configured to be:
in a light transmissive state during the first time period of the preset period; and
in a light shading state during the second time period of the preset period.

18. The display system according to claim 15, wherein the shutter glasses and the display apparatus are paired using a pulse signal.

19. The display system according to claim 16, wherein the shutter glasses and the display apparatus are paired using a pulse signal.

20. The display system according to claim 17, wherein the shutter glasses and the display apparatus are paired using a pulse signal.
